(19) United States
(12) Patent Application Publication
(10) Pub. No.: US 2024/0178241 A1
(43) Pub. Date: May 30, 2024

(54) ARRAY SUBSTRATE

(71) Applicant: TCL CHINA STAR OPTOELECTRONICS TECHNOLOGY CO., LTD., Shenzhen (CN)

(72) Inventors: Hui YANG, Shenzhen (CN); Fan YANG, Shenzhen (CN)

(73) Assignee: TCL CHINA STAR OPTOELECTRONICS TECHNOLOGY CO., LTD., Shenzhen (CN)

(21) Appl. No.: 18/191,701

(22) Filed: Mar. 28, 2023

(30) Foreign Application Priority Data
Nov. 24, 2022 (CN) 202211486909.3

(51) Int. Cl. H01L 27/12; G02F 1/1343; G02F 1/136; G02F 1/1362

(52) U.S. Cl. CPC H01L 27/1255; G02F 1/134309; G02F 1/13606; G02F 1/136213; G02F 1/136286; H01L 27/124; G02F 2201/40

(57) ABSTRACT

The present application provides an array substrate, the array substrate includes a gate electrode, a compensation electrode, an array substrate side common electrode, and a source electrode. Disposing a source electrode portion and a compensation portion of the source electrode on two opposite sides of a storage capacitor portion and connecting the source electrode portion and the compensation portion to the storage capacitor portion can reduce an occupying area of the source electrode to improve an aperture rate of the array substrate.

### FIELD OF INVENTION

The present application relates to a field of display technologies, especially to an array substrate.

### BACKGROUND OF INVENTION

A liquid crystal displays (LCD) is currently the most widely used display. Compared to a traditional cathode ray tube (CRT) display, the liquid crystal display has advantages such as thin body, low power consumption, low voltage driving, etc. A display region of the liquid crystal display comprises a plurality of pixel regions, and each pixel region is a region defined by two gate lines and two data lines, and a thin film transistor and a pixel electrode are disposed in the pixel region as a switch assembly.

With reference to FIG. 1, a gate electrode 11, a source electrode 12, a drain electrode 13, and a pixel electrode 14 are disposed on an array substrate of a liquid crystal display panel. The source electrode 12 and the drain electrode 13 are disposed, and the gate electrode 11 are disposed in different film layers. An overlapping part of the source electrode 12 and the gate electrode 11 would generate parasitic capacitor (namely, gate source capacitor), and the parasitic capacitor would affect an amount of an input voltage. During manufacturing the array substrate, because of a process deviation, the source electrode 12 would be displaced in left-right direction. When the source electrode 12 is displaced in a right direction, an overlapping area of the source electrode 12 and the gate electrode 11 increases and a parasitic capacitor of the source electrode 12 and the gate electrode 11 also increases such that the input voltage also increase. At this time, the liquid crystal display panel would generate some alternating voltage to easily cause issues of image flickering and afterimage.

With reference to FIG. 2, to solve an issue of variation of the parasitic capacitor between the gate electrode 11 and the source electrode 12 resulting from a process deviation, a long arm 120 and a compensation portion 121 are additionally disposed on the source electrode 12. The compensation portion 121 and the source electrode portion 122 are connected to the long arm 120. a compensation electrode 110 is additionally disposed on the gate electrode 11 and is connected to the gate electrode 11, and the compensation portion 121 overlaps the compensation electrode 110 to assure that the parasitic capacitor between the source electrode 12 and the gate electrode 11 keeps constant when the source electrode 12 is displaced. However, the additionally disposed long arm 120 would compress an area of the pixel electrode 14 in a vertical direction such that an aperture rate of the array substrate decreases to further result in decrease of a transmittance of the display panel.

As described above, the conventional array substrate has an issue of a lowered aperture rate of the array substrate due to mitigation of variation of the gate source capacitor. Therefore, it is necessary to provide an array substrate to mitigate such defect.

### SUMMARY OF INVENTION

An embodiment of the present application provides an array substrate that can increase an aperture rate of the array substrate under the basis of a conventional gate source capacitor compensation.

The embodiment of the present application provides an array substrate, comprising a gate electrode, a compensation electrode disposed on a side of the gate electrode and connected to the gate electrode, an array substrate side common electrode, and a source electrode, wherein the source electrode and the gate electrode are disposed in different layers, and the source electrode and the compensation electrode are disposed in different layers;

wherein the source electrode comprises a storage capacitor portion, a source electrode portion, and a compensation portion, the source electrode portion and the compensation portion are disposed on two opposite sides of the storage capacitor portion and are connected to the storage capacitor portion, a part of the source electrode portion overlaps the gate electrode, a part of the compensation portion overlaps the compensation electrode, the source electrode and the array substrate side common electrode are disposed in different layers, in an extension direction of the source electrode portion, a part of the storage capacitor portion intersecting the source electrode portion at least partially overlaps the array substrate side common electrode; and in an extension direction of the compensation portion, a part of the storage capacitor portion intersecting the compensation portion at least partially overlaps the array substrate side common electrode.

According to an embodiment of the present application, the array substrate comprises a gate line and a pixel electrode, the gate electrode and the compensation electrode are disposed on a same side of the gate line and are connected to the gate line, and the pixel electrode and the source electrode are disposed in different layers and contact the storage capacitor portion through a contact hole; and

the contact hole is disposed between the gate electrode and the compensation electrode, and in a direction perpendicular to the extension direction of the source electrode portion or the compensation portion, a minimum distance between the contact hole and the gate line is less than or equal to a width of the gate electrode.

According to an embodiment of the present application, in a direction perpendicular to the extension direction of the source electrode portion or the compensation portion, a distance between the storage capacitor portion and the gate line is less than or equal to a distance between the source electrode portion and the gate line, and the distance between the storage capacitor portion and the gate line is less than or equal to a distance between the compensation portion and the gate line.

According to an embodiment of the present application, the extension direction of the source electrode portion is parallel to the extension direction of the compensation portion, and the extension direction of the source electrode portion is opposite to the extension direction of the compensation portion.

According to an embodiment of the present application, in a direction perpendicular to the extension direction of the source electrode portion or the compensation portion, a width of a part of the source electrode portion is equal to a width of the compensation portion.

According to an embodiment of the present application, in the extension direction of the source electrode portion or the compensation portion, the source electrode portion at least partially overlaps the compensation portion or is at least partially staggered with the compensation portion.

According to an embodiment of the present application, in the extension direction of the source electrode portion or the compensation portion, an edge of one of the storage capacitor portion and the array substrate side common electrode extends beyond an edge of the other on the same side; and

in a direction perpendicular to the extension direction of the source electrode portion or the compensation portion, an edge of one of the storage capacitor portion and the array substrate side common electrode extends beyond an edge of the other on the same side.

According to an embodiment of the present application, in the extension direction of the source electrode portion or the compensation portion, a distance between the edge of the storage capacitor portion and an edge of the array substrate side common electrode on the same side ranges from 3 to 5 microns, and a distance between the gate electrode and the storage capacitor portion is greater than or equal to 4.3 microns.

According to an embodiment of the present application, in the direction perpendicular to the extension direction of the source electrode portion or the compensation portion, and a distance between the edge of the storage capacitor portion and an edge of the array substrate side common electrode on the same side ranges from 3 to 5 microns, a width of the source electrode portion ranges from 7 to 10 microns.

According to an embodiment of the present application, in a direction perpendicular to the extension direction of the source electrode portion or the compensation portion, and a width of the source electrode portion ranges from 7 to 10 microns.

According to an embodiment of the present application, the array substrate further comprises a drain electrode, in the extension direction of the source electrode portion or the compensation portion, and a distance between the drain electrode and an edge of a side of the gate electrode near the storage capacitor portion is greater than or equal to 7 microns.

Advantages of the embodiment of the present application: The embodiment of the present application provides an array substrate. The array substrate comprises a gate electrode, a compensation electrode, and an array substrate side common electrode, the compensation electrode is disposed on a side of the gate electrode, and is connected to the gate electrode. The array substrate further comprises a source electrode. The source electrode and the gate electrode are disposed in different layers. The source electrode and the compensation electrode are disposed in different layers. The source electrode comprises a storage capacitor portion, a source electrode portion, and a compensation portion. A part of the source electrode portion overlaps the gate electrode and a part of the compensation portion overlaps the compensation electrode to guarantee a constant parasitic capacitor between the gate electrode and the source electrode. Disposing the source electrode portion and the compensation portion on two opposite sides of the storage capacitor portion and using the storage capacitor portion to connect the source electrode portion and the compensation portion can reduce an occupying area of the source electrode to increase an aperture rate of the array substrate.

### DESCRIPTION OF DRAWINGS

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may also acquire other figures according to the appended figures without any creative effort.

FIG. 1 is a schematic structural view of a first pixel region of a conventional technology;

FIG. 2 is a schematic structural view of a second pixel region of a conventional technology;

FIG. 3 is a schematic structural view of a first pixel region provided by the embodiment of the present application;

FIG. 4 is a schematic view of a partial film layer of the first pixel region provided by the embodiment of the present application;

FIG. 5 is a schematic structural view of a second pixel region provided by the embodiment of the present application;

FIG. 6 is a schematic structural view of a third pixel region provided by the embodiment of the present application;

FIG. 7 is a schematic structural view of a fourth pixel region provided by the embodiment of the present application;

FIG. 8 is a schematic structural view of a fifth pixel region provided by the embodiment of the present application; and

FIG. 9 is a schematic structural view of the display panel provided by the embodiment of the present application.

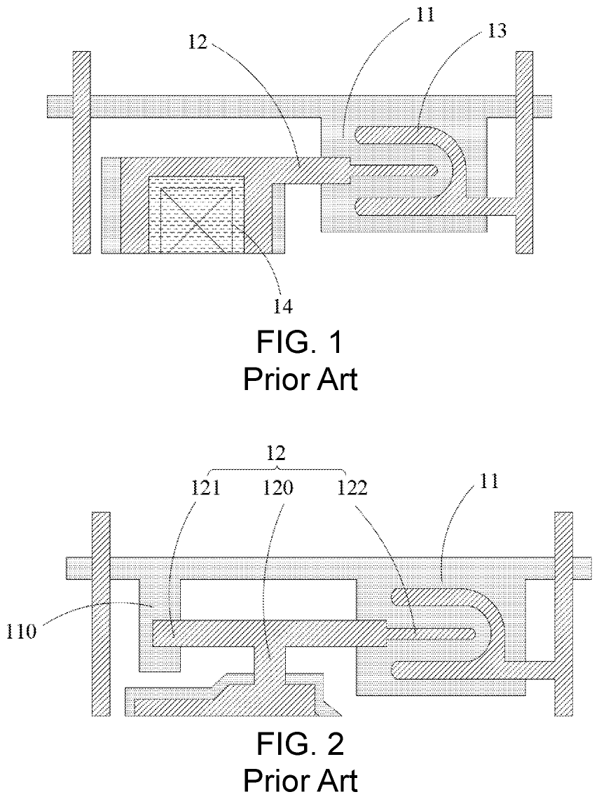

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.

The present application will be further described in combination with attached drawings and specific embodiments.

The embodiment of the present application provides an array substrate and a display panel that can increase an aperture rate of the array substrate and the display panel under the basis of a conventional gate source capacitor compensation.

The embodiment of the present application provides an array substrate, a plurality of pixel region, each pixel region is a region defined by two gate lines GL and two data lines DL. A thin film transistor and a pixel electrode are disposed in the pixel region as a switch assembly.

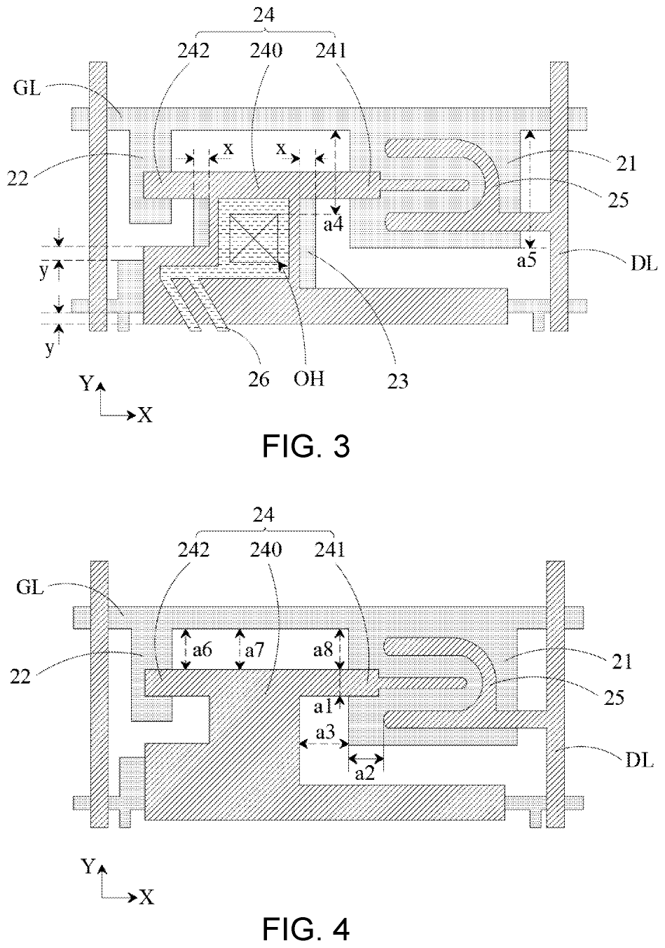

With reference to FIG. 3, the array substrate can comprise a gate electrode 21 and a compensation electrode 22. The compensation electrode 22 is disposed on a side of the gate electrode 21. The gate electrode 21 is connected to the compensation electrode 22. Namely, the gate electrode 21 is electrically connected to the compensation electrode 22.

In the embodiment of the present application, the gate electrode 21 and the compensation electrode 22 are disposed at an interval. The interval is formed between the gate electrode 21 and the compensation electrode 22, and the gate electrode 21 and the compensation electrode 22 can be located in the same film layer structure.

In some other embodiments, according to choices and specific demands of actual conditions, the gate electrode 21 and the compensation electrode 22 can also be located in different film layer structures as long as it is guaranteed that the gate electrode 21 is connected to the compensation electrode 22 and an interval is formed between the gate electrode 21 and the compensation electrode 22 along a direction of a plane parallel to the gate electrode 21 or the compensation electrode 22. No limit is here.

Furthermore, the array substrate can further comprise a source electrode 24. The source electrode 24 and the gate electrode 21 are disposed in different layers. The source electrode 24 and the compensation electrode 22 are disposed in different layers. Namely, the gate electrode 21 and the compensation electrode 22, and the source electrode 24 are in different film layer structures.

For example, the array substrate can comprise an underlay, a first metal layer, and a second metal layer. The first metal layer can be disposed between the underlay and the second metal layer. The first metal layer can als be called gate electrode metal layer. The gate electrode 21 and the compensation electrode 22 can be disposed on the first metal layer. The second metal layer can also be called source and drain electrode metal layer. The source electrode 24 can be disposed on the second metal layer.

Furthermore, the source electrode 24 comprises a storage capacitor portion 240, a source electrode portion 241, and a compensation portion 242. The source electrode portion 241 and the compensation portion 242 are disposed on two sides of the storage capacitor portion 240 and are connected to the storage capacitor portion 240. A part of the source electrode portion 241 overlaps the gate electrode 21. A part of the compensation portion 242 overlaps the compensation electrode 22.

In the embodiment of the present application, the source electrode portion 241 is disposed on a side of the storage capacitor portion 240 near the gate electrode 21. The compensation portion 242 is disposed on a side of the storage capacitor portion 240 near the compensation electrode 22.

It should be explained that the compensation electrode 22 is disposed on a side of the gate electrode 21, the compensation electrode 22 is connected to the gate electrode 21, and the storage capacitor portion 240 disposed between the source electrode portion 241 and the compensation portion 242 such that the storage capacitor portion 240 extends toward the gate electrode 21 to form the source electrode portion 241. A part of the source electrode portion 241 overlaps the gate electrode 21. The storage capacitor portion 240 extends toward the compensation electrode 22 to form the compensation portion 242. A part of the compensation portion 242 overlaps the compensation electrode 22. Under such structure, a parasitic capacitor between the source electrode 24 and the gate electrode 21 is equal to a sum of a capacitor between the source electrode portion 241 and the gate electrode 21 and a capacitor between the compensation portion 242 and the compensation electrode 22.

When the source electrode 24 is displaced right due to the process, an overlapping area of the source electrode portion 241 and the gate electrode 21 would increase, and a capacitor between the source electrode portion 241 and the gate electrode 21 would also increase, an overlapping area of the compensation portion 242 and the compensation electrode 22 would decrease, and a capacitor between the compensation portion 242 and the compensation electrode 22 would also decrease. A capacitor variation value between the source electrode portion 241 and the gate electrode 21 is equal to a capacitor variation value between the compensation portion 242 and the compensation electrode 22 such that a parasitic capacitor between the source electrode 24 and the gate electrode 21 keeps constant. Similarly, when the source electrode 24 is displaced left due to the process, a parasitic capacitor between the source electrode 24 and the gate electrode 21 keeps constant. Therefore, the technical solution provided by the embodiment of the present application can solve an issue of gate source capacitor variation resulting from a process deviation.

Furthermore, the array substrate further comprises array substrate side common electrode 23, the array substrate side common electrode 23 and the gate electrode 21 are disposed in the same layer, and the array substrate side common electrode 23 is disposed at an interval from the gate electrode 21. The array substrate side common electrode 23 and the source electrode 24 are disposed in different layers, and the array substrate side common electrode 23 overlaps the storage capacitor portion 240 of the source electrode 24 to form a storage capacitor. The storage capacitor portion 240 can serve as an upper electrode plate of the storage capacitor. The array substrate side common electrode 23 can serve as a lower electrode plate of the storage capacitor.

Furthermore, in an extension direction of the source electrode portion 241, a part of the storage capacitor portion 240 intersecting the source electrode portion 241 at least partially overlaps the array substrate side common electrode 23. In an extension direction of the compensation portion 242, a part of the storage capacitor portion 240 intersecting the compensation portion 242 at least partially overlaps the array substrate side common electrode 23.

With reference to FIG. 3, both the source electrode portion 241 and the compensation portion 242 are strip-like. The extension direction of the source electrode portion 241 is parallel to the extension direction of the compensation portion 242, and both are parallel to the first direction X. The extension direction of the source electrode portion 241 is opposite to the extension direction of the compensation portion 242. In the first direction X, the part of the storage capacitor portion 240 intersecting the source electrode portion 241 partially overlaps the array substrate side common electrode 23, and the part of the storage capacitor portion 240 intersecting the compensation portion 242 partially overlaps the array substrate side common electrode 23.

The part of the storage capacitor portion 240 intersecting the source electrode portion 24 and the part of the storage capacitor portion 240 intersecting the compensation portion 242 can be deemed as parts of the storage capacitor portion 240 between the source electrode portion 241 and the compensation portion 242 and connected to the source electrode portion 241 and the compensation portion 242 respectively. The parts partially overlap the array substrate side common electrode 23. A part of the storage capacitor portion 240 not intersecting the source electrode portion 241 and the compensation portion 242 can also be partially overlapped to commonly form a storage capacitor. Under such structure, the source electrode portion 241 can be deemed to directly connect with the compensation portion 242 and the storage capacitor portion 240. It should be explained that compared to the conventional technology in FIG. 2, the technical solution provided by the embodiment of the present application can cancel a long arm design of the source electrode in FIG. 2, and the source electrode portion 241 and compensation portion 242 are directly connected to the storage capacitor portion 240 such that an occupying space of the source electrode 24 in the second direction Y can be reduced to increase an aperture rate of the pixel region. In one of the embodiments, using the technical solution provided by the embodiment of the present application can save a space of about 12 microns in the second direction Y.

With reference to FIG. 3, the array substrate further comprises a gate line GL and a pixel electrode 26. The gate electrode 21 and the compensation electrode 22 are disposed on the same side of the gate line GL. The compensation electrode 22 is connected to the gate electrode 21 through the gate line GL. Under such structure, a compressed space of the pixel electrode due to the additional disposed compensation electrode 22 can be prevented to guarantee an aperture rate of the pixel region.

The pixel electrode 26 and the source electrode 24 are disposed in different layers, and the pixel electrode 26 contacts the storage capacitor portion 240 through a contact hole OH. The pixel electrode 26 can be disposed on a side of the source electrode 24 away from the underlay.

It should be explained that in FIG. 3 and other attached drawings, only block regions are used to represent the pixel electrode 26. Shape and size of pixel electrode 26 in FIG. 3 and other attached drawings are not shape and size of the pixel electrode 26 in an actual application.

Furthermore, the contact hole OG is disposed between the gate electrode 21 and the compensation electrode 22. In a direction perpendicular to an extension direction of the source electrode portion 241 or the compensation portion 242, a minimum distance a4 between the contact hole OH and the gate line GL is less than or equal to a width a5 of the gate electrode 21. Under such structure, digging a region between the gate electrode 21 and the compensation electrode 22 to form the contact hole OH to communicate the pixel electrode 26 and the source electrode 24 not only reduces a distance between the contact hole OH and the gate line GL and reduces an occupying space of the contact hole OH but also increases an area of the pixel electrode 26 such that an aperture rate of the pixel region is raised to further increase a transmittance of the array substrate.

In one of the embodiments, with reference to FIG. 3, the contact hole OG is defined between the gate electrode 21 and the compensation electrode 22. In a direction perpendicular to the source electrode portion 241 or the extension direction of the compensation portion 242, the minimum distance a4 between the contact hole OH and the gate line GL is less than the width a5 of the gate electrode 21. In some other embodiments, the minimum distance a4 between the contact hole OH and the gate line GL can also be equal to the width a5 of the gate electrode 21.

Furthermore, the array substrate further comprises a drain electrode 25 and an active layer (not shown in the figures). The active layer and the gate electrode 21 are disposed in different layers, and the active layer at least partially overlaps the gate electrode 21. The drain electrode 25 and the gate electrode 21 are disposed in different layers. The drain electrode 25 and the source electrode 24 can be disposed in the same layer and be connected to the active layer.

In the embodiment of the present application, the active layer can be disposed on a side of the gate electrode 21 away from the substrate, and the source electrode 24 and the drain electrode 25 can be disposed on a side of the active layer away from the gate electrode 21. In some other embodiments, a lamination sequence of the gate electrode 21, the active layer, the source electrode 24, and the drain electrode 25 can also be modified adequately, and no limit is here.

Furthermore, in the embodiment of the present application, the pixel electrode in the array substrate is a 4-domain structure. In some other embodiments, the technical solution provided by the present application is also applicable for a pixel electrode of a 8-domain structure, and no limit is here.

Furthermore, the array substrate further comprises a data line DL. The gate line GL and the gate electrode 21 are disposed in the same layer. The data line DL and the source electrode 24 are disposed in the same layer. The gate line GL is disposed and extends along a first direction X. The data line DL is disposed and extends along a second direction Y The first direction X intersects the second direction Y.

In the embodiment of the present application, the first direction X and the second direction Y can be disposed perpendicularly. In some other embodiments, according to choices and specific demands of actual conditions, the first direction X and the second direction Y can have another included angle, and no limit is here.

In the embodiment of the present application, the drain electrode 25 is connected to the data line DL, namely, the drain electrode 25 is electrically connected to the data line DL.

Furthermore, with reference to FIG. 3, both the source electrode portion 241 and the compensation portion 242 are strip-like. An extension direction of the source electrode portion 241 is parallel to an extension direction of the compensation portion 242, and both are parallel to the first direction X. An extension direction of the source electrode portion 241 is opposite to an extension direction of the compensation portion 242. Under such structure, a structure of the source electrode 24 can be simplified to facilitate manufacturing without increasing manufacturing difficulty of the array substrate.

Furthermore, in a direction perpendicular to the extension direction of the source electrode portion or the compensation portion, a width of a part of the source electrode portion is equal to a width of the compensation portion.

With reference to FIG. 3, in the second direction Y, the width of the source electrode portion 241 is equal to the width of the compensation portion 242. Under such structure, even the source electrode 24 is displaced due to process deviation, it can also be guaranteed that a variation value of an overlapping area between the source electrode portion 241 and the gate electrode 21 is equal to a variation value of an overlapping area between the compensation portion 242 and the compensation electrode 22 to further guarantee a constant parasitic capacitor between the source electrode 24 and the gate electrode 21.

Furthermore, a distance a7 between the storage capacitor portion 240 and the gate line GL is less than or equal to a distance a8 between the source electrode portion 241 and the gate line GL. The distance a7 between the storage capacitor portion 240 and the gate line GL is less than or equal to a distance a6 between the compensation portion 242 and the gate line GL.

In one of the embodiments, with reference to FIG. 4, the distance a7 between the storage capacitor portion 240 and the gate line GL is equal to the distance a8 between the source electrode portion 241 and the gate line GL, the distance a7 between the storage capacitor portion 240 and the gate line GL is equal to the distance a6 between the compensation portion 242 and the gate line GL. Namely, an edge of a side of the storage capacitor portion 240 near the gate line GL and an edge of a side of the source electrode portion 241 near the gate line GL is flush with an edge of a side of the compensation portion 242 near the gate line GL. In the first direction X, the source electrode portion 241 completely overlaps the compensation portion 242, namely, the source electrode portion 241 is located in an extension line of the compensation portion 242 along the first direction X. Under such structure, an occupying space of the source electrode 24 can be reduced to facilitate increase of the area of the pixel electrode to increase an aperture rate of the pixel region.

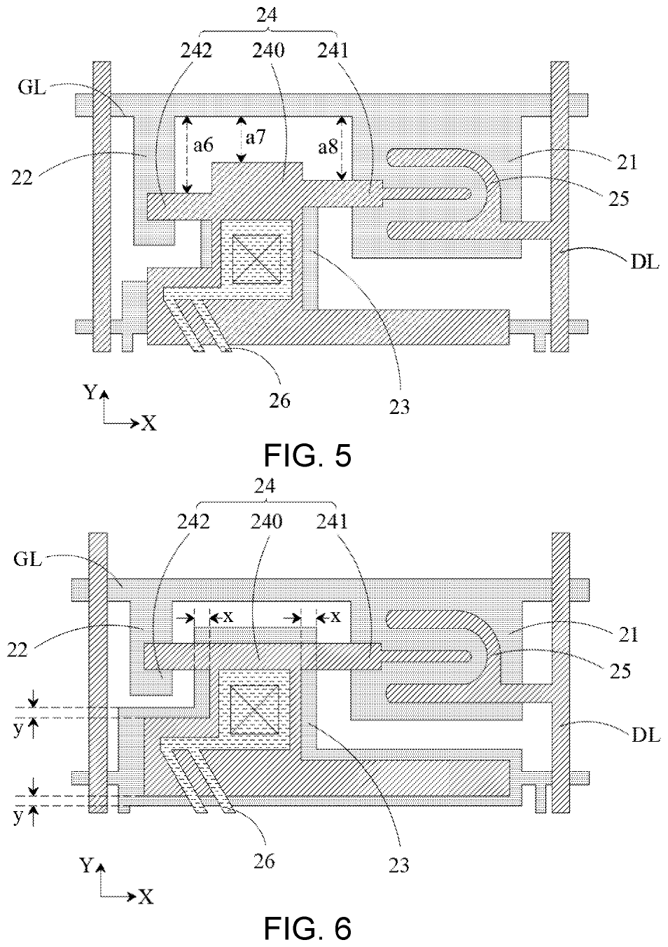

In one of the embodiments, with reference to FIG. 5, in the second direction Y, the distance a7 between the storage capacitor portion 240 and the gate line GL is less than the distance a8 between the source electrode portion 241 and the gate line GL. The distance a7 between the storage capacitor portion 240 and the gate line GL is less than the distance a6 between the compensation portion 242 and the gate line GL. In the first direction X, the source electrode portion 241 partially overlaps the compensation portion 242, and no limit is here.

In one of the embodiments, in the first direction X, the source electrode portion 241 and the compensation portion 242 can also be staggered completely. Namely, the source electrode portion 241 is disposed around an extension line of the compensation portion 242. Under such structure, an area of the source electrode 24 can increase to decrease a contact resistance of the source electrode 24 to reduce energy consumption and improve performance of the thin film transistor.

Furthermore, in an extension direction of the source electrode portion 241 or the compensation portion 242, an edge of one of the storage capacitor portion 240 and the array substrate side common electrode 23 extends beyond another edge one the same side. In a direction perpendicular to the extension direction of the source electrode portion 241 or the compensation portion 242, the storage capacitor portion 240 and one edge of the common electrode 23 of the side of the array substrate edge extend beyond another edge at the same side.

In one of the embodiments, with reference to FIG. 3, in the first direction X, a left side edge of the array substrate side common electrode 23 extends beyond a left side edge of the storage capacitor portion 240, a right side edge of the array substrate side common electrode 23 extends beyond a right side edge of the storage capacitor portion 240. In the second direction Y, the upper side edge of the storage capacitor portion 240 extends beyond the upper side edge of the array substrate side common electrode 23. A lower side edge of the storage capacitor portion 240 extends beyond a lower side edge of the array substrate side common electrode 23. Under such structure, alignment accuracy of the source electrode 24 can be guaranteed to reduce an offset of the source electrode 24 such that variation of the parasitic capacitor between the source electrode 24 and the gate electrode 21 can be mitigated.

Furthermore, in the extension direction of the source electrode portion or the compensation portion, a distance between the edge of the storage capacitor portion and an edge of the array substrate side common electrode on the same side ranges from 3 to 5 microns.

With reference to FIG. 3, in the first direction X, the left side edge of the array substrate side common electrode 23 extends beyond the left side edge of the storage capacitor portion 240, and a distance x of the left side edge of the array substrate side common electrode 23 extending beyond the left side edge of the storage capacitor portion 240 ranges from 3 to 5 microns. The right side edge of the array substrate side common electrode 23 extends beyond the right side edge of the storage capacitor portion 240, and a distance x of the right side edge of the array substrate side common electrode 23 extending beyond the right side edge of the storage capacitor portion 240 ranges from 3 to 5 microns. In an actual application, a value of x can be but is not limited to 3, 3.5, 4, 4.5 or 5, as long as it ranges from 3 to 5.

In the second direction Y, an upper side edge of the storage capacitor portion 240 extends beyond an upper side edge of the array substrate side common electrode 23, and a distance y of the upper side edge of the storage capacitor portion 240 extending beyond the upper side edge of the array substrate side common electrode 23 ranges from 3 to 5 microns. The upper side edge of the storage capacitor portion 240 extends beyond the lower side edge of the array substrate side common electrode 23, and a distance y of the upper side edge of the storage capacitor portion 240 extending beyond the lower side edge of the array substrate side common electrode 23 ranges from 3 to 5 microns. In particular, a value of y can be but is not limited to 3, 3.5, 4, 4.5 or 5, as long as it ranges from 3 to 5.

Furthermore, in a direction perpendicular to the extension direction of the source electrode portion or the compensation portion, a width of the source electrode portion ranges from 7 to 10 microns.

With reference FIG. 4, in the second direction Y, a width a1 of the source electrode portion 241 ranges from 7 to 10 microns. In particular, a value of a1 can be but is not limited to 7, 8, 9, or 10, as long as it ranges from 7 to 10.

Furthermore, a distance between the drain electrode and an edge of a side of the gate electrode near the storage capacitor portion is greater than or equal to 7 microns.

With reference FIG. 4, in the first direction X, a distance a2 between the drain electrode 25 and an edge of a side of the gate electrode 21 near the storage capacitor portion 240 is greater than or equal to 7 microns. In particular, a value of a2 can be but is not limited to 7, 7.5, 8, 8.5 or 9, as long as it is greater than or equal to 7.

Furthermore, a distance between the gate electrode and the storage capacitor portion is greater than or equal to 4.3 microns.

With reference FIG. 4, in the first direction X, a distance a3 between the gate electrode 21 and the storage capacitor portion 240 is greater than or equal to 4.3 microns. In particular, a value of a3 can be but is not limited to 4.3, 4.5, 4.8, 5 or 6, as long as it is greater than or equal to 4.3.

Under such structure, the width a1 of the source electrode portion 241 decreases, the distance a2 between the drain electrode 25 and an edge of a side of the gate electrode 21 near the storage capacitor portion 240 increases, and the distance a3 between the storage capacitor portion 240 and the gate electrode 21 increases such that a transmission path of an electron is lengthened and a transmission capability of the electron is weakened to prevent the electron from passing through a path of the source electrode portion 241, the gate electrode 21, and the storage capacitor portion 240 and moving to the storage capacitor to cause a lowered the storage capacitor, a lowered pixel maintaining voltage, and leakage to cause a defect such as spots.

In one of the embodiments, with reference to FIG. 6, a periphery edge of the array substrate side common electrode 23 can extend beyond a periphery edge of the storage capacitor portion 240. Namely, the storage capacitor portion 240 is retracted relative to a periphery of the array substrate side common electrode 23. Left, right, upper, and lower side edges of the array substrate side common electrode 23 all extend beyond an edge of the same side of the storage capacitor portion 240, and a distance extending beyond ranges from 3 to 5 microns. In the first direction X, the part of the storage capacitor portion 240 intersecting the source electrode portion 241 can completely overlap the array substrate side common electrode 23. The part of the storage capacitor portion 240 intersecting the compensation portion 242 can also completely overlap the array substrate side common electrode 23. Under such structure, alignment accuracy of the source electrode 24 can also be guaranteed to reduce an offset of the source electrode 24 such that variation of the parasitic capacitor between the source electrode 24 and the gate electrode 21 can be mitigated.

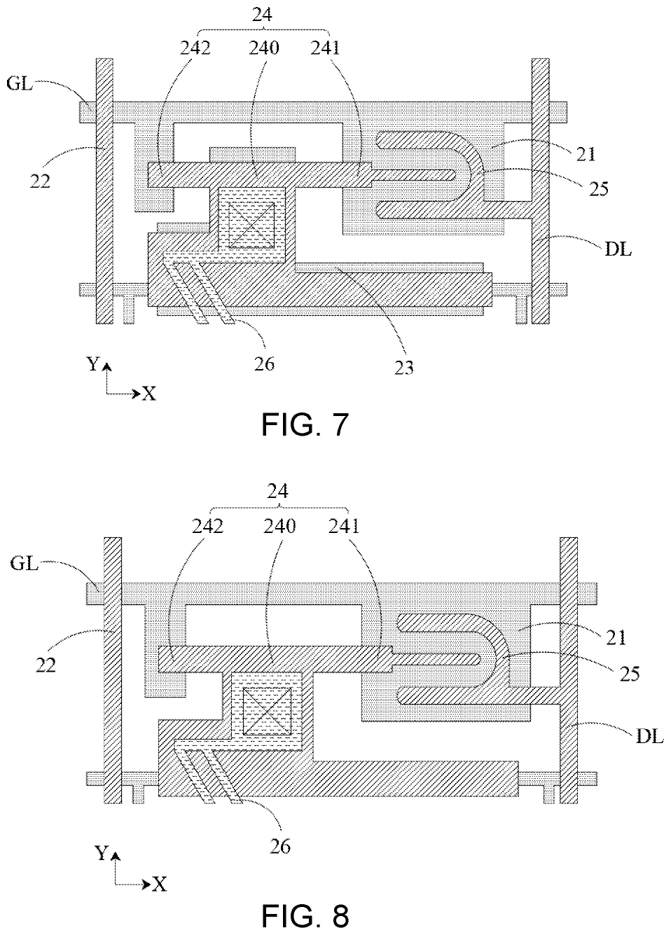

In one of the embodiments, with reference to FIG. 7, in the first direction X, the left side edge of the storage capacitor portion 240 extends beyond the left side edge of the array substrate side common electrode 23, the right side edge of the storage capacitor portion 240 extends beyond the right side edge of the array substrate side common electrode 23; in the second direction Y The upper side edge of the array substrate side common electrode 23 extends beyond the upper side edge of the storage capacitor portion 240. The lower side edge of the array substrate side common electrode 23 extends beyond the lower side edge of the storage capacitor portion 240, and a distance extending beyond ranges from 3 to 5 microns. Under such structure, alignment accuracy of the source electrode 24 can also be guaranteed to reduce an offset of the source electrode 24 such that variation of the parasitic capacitor between the source electrode 24 and the gate electrode 21 can be mitigated.

In one of the embodiments, with reference to FIG. 8, a periphery edge of the storage capacitor portion 240 can extend beyond the periphery edge of the array substrate side common electrode 23. Namely, the storage capacitor portion 240 is expanded outward relative to the periphery of the array substrate side common electrode 23. Left, right, upper, and lower side edges of the storage capacitor portion 240 all extend beyond an edge on the same side of the array substrate side common electrode 23, and a distance extending beyond ranges from 3 to 5 microns. Under such structure, alignment accuracy of the source electrode 24 can also be guaranteed to reduce an offset of the source electrode 24 such that variation of the parasitic capacitor between the source electrode 24 and the gate electrode 21 can be mitigated. It should be explained that because the array substrate side common electrode 23 is covered by the storage capacitor portion 240, FIG. 8 does not illustrate the array substrate side common electrode 23.

In an actual application, according to choices and specific demands of actual conditions, a combination of expansion or retraction of the array substrate side common electrode 23 and the storage capacitor portion 240 along the first direction X and the second direction Y can be adjusted according to a space, and no limit is here.

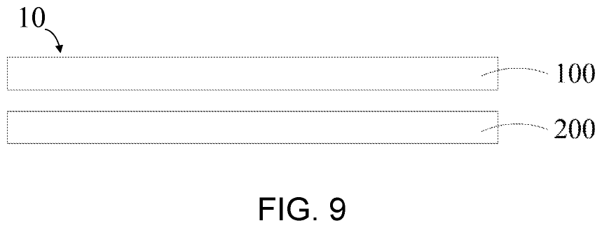

According to the array substrate provided by the embodiment of the present application, the embodiment of the present application further provides a display panel. With reference to FIG. 9, the display panel 10 comprises an opposite substrate 100, and the array substrate 200 as above. The opposite substrate 100 is disposed opposite to the array substrate 200. The display panel can further comprise a liquid crystal layer, the liquid crystal layer is disposed between the opposite substrate 100 and the array substrate 200.

According to the display panel provided by the above embodiment of the present application, the embodiment of the present application further provides a display device. The display device can comprise a backlight module and the display panel as described above, and the backlight module is disposed on a side of the display panel.

Advantages of the embodiment of the present application: The embodiment of the present application provides an array substrate. The array substrate comprises a gate electrode, a compensation electrode, and an array substrate side common electrode, the compensation electrode is disposed on a side of the gate electrode and is connected to the gate electrode. The array substrate further comprises a source electrode. The source electrode and the gate electrode are disposed in different layers. The source electrode and the compensation electrode are disposed in different layers. The source electrode comprises a storage capacitor portion, a source electrode portion, and a compensation portion. A part of the source electrode portion overlaps the gate electrode and a part of the compensation portion overlaps the compensation electrode to guarantee a constant parasitic capacitor between the gate electrode and the source electrode. Disposing the source electrode portion and the compensation portion on two opposite sides of the storage capacitor portion and using the storage capacitor portion to connect the source electrode portion and the compensation portion can reduce an occupying area of the source electrode to increase an aperture rate of the array substrate.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. An array substrate, comprising:
a gate electrode,
a compensation electrode disposed on a side of the gate electrode and connected to the gate electrode;
an array substrate side common electrode, and
a source electrode, wherein the source electrode and the gate electrode are disposed in different layers, and the source electrode and the compensation electrode are disposed in different layers;
wherein the source electrode comprises a storage capacitor portion, a source electrode portion, and a compensation portion, the source electrode portion and the compensation portion are disposed on two opposite sides of the storage capacitor portion and are connected to the storage capacitor portion, a part of the source electrode portion overlaps the gate electrode, a part of the compensation portion overlaps the compensation electrode, the source electrode and the array substrate side common electrode are disposed in different layers, in an extension direction of the source electrode portion, a part of the storage capacitor portion intersecting the source electrode portion at least partially overlaps the array substrate side common electrode; and in an extension direction of the compensation portion, a part of the storage capacitor portion intersecting the compensation portion at least partially overlaps the array substrate side common electrode.

2. The array substrate according to claim 1, further comprising
a gate line; and
a pixel electrode;
wherein the gate electrode and the compensation electrode are disposed on a same side of the gate line and are connected to the gate line, and the pixel electrode and the source electrode are disposed in different layers and contact the storage capacitor portion through a contact hole; and
wherein the contact hole is disposed between the gate electrode and the compensation electrode, and in a direction perpendicular to the extension direction of the source electrode portion or the compensation portion, a minimum distance between the contact hole and the gate line is less than or equal to a width of the gate electrode.

3. The array substrate according to claim 2, wherein in a direction perpendicular to the extension direction of the source electrode portion or the compensation portion, a distance between the storage capacitor portion and the gate line is less than or equal to a distance between the source electrode portion and the gate line, and the distance between the storage capacitor portion and the gate line is less than or equal to a distance between the compensation portion and the gate line.

4. The array substrate according to claim 1, wherein the extension direction of the source electrode portion is parallel to the extension direction of the compensation portion, and the extension direction of the source electrode portion is opposite to the extension direction of the compensation portion.

5. The array substrate according to claim 4, wherein in a direction perpendicular to the extension direction of the source electrode portion or the compensation portion, a width of a part of the source electrode portion is equal to a width of the compensation portion.

6. The array substrate according to claim 4, wherein in the extension direction of the source electrode portion or the compensation portion, the source electrode portion at least partially overlaps the compensation portion or is at least partially staggered with the compensation portion.

7. The array substrate according to claim 4, wherein in the extension direction of the source electrode portion or the compensation portion, an edge of one of the storage capacitor portion and the array substrate side common electrode extends beyond an edge of the other on the same side; and
in a direction perpendicular to the extension direction of the source electrode portion or the compensation portion, an edge of one of the storage capacitor portion and the array substrate side common electrode extends beyond an edge of the other on the same side.

8. The array substrate according to claim 7, wherein in the extension direction of the source electrode portion or the compensation portion, a distance between the edge of the storage capacitor portion and an edge of the array substrate side common electrode on the same side ranges from 3 to 5 microns, and a distance between the gate electrode and the storage capacitor portion is greater than or equal to 4.3 microns.

9. The array substrate according to claim 7, wherein in the direction perpendicular to the extension direction of the source electrode portion or the compensation portion, and a distance between the edge of the storage capacitor portion and an edge of the array substrate side common electrode on the same side ranges from 3 to 5 microns, a width of the source electrode portion ranges from 7 to 10 microns.

10. The array substrate according to claim 1, wherein the array substrate further comprises a drain electrode, in the extension direction of the source electrode portion or the compensation portion, and a distance between the drain electrode and an edge of a side of the gate electrode near the storage capacitor portion is greater than or equal to 7 microns.

11. An array substrate, comprising a gate electrode, a compensation electrode disposed on a side of the gate electrode and connected to the gate electrode, an array substrate side common electrode, and a source electrode, wherein the compensation electrode, the source electrode, and the gate electrode are disposed in different layers, and the source electrode and the compensation electrode are disposed in different layers;
wherein the source electrode comprises a storage capacitor portion, a source electrode portion, and a compensation portion, the source electrode portion and the compensation portion are disposed on two opposite sides of the storage capacitor portion and are connected to the storage capacitor portion, a part of the source electrode portion overlaps the gate electrode, a part of the compensation portion overlaps the compensation electrode, the source electrode and the array substrate side common electrode are disposed in different layers, in an extension direction of the source electrode portion, a part of the storage capacitor portion intersecting the source electrode portion at least partially overlaps the array substrate side common electrode; and in an extension direction of the compensation portion, a part of the storage capacitor portion intersecting the compensation portion at least partially overlaps the array substrate side common electrode;
wherein the array substrate comprises a gate line and a pixel electrode, the gate electrode and the compensation electrode are disposed on a same side of the gate line and are connected to the gate line, and the pixel electrode and the source electrode are disposed in different layers and contact the storage capacitor portion through a contact hole;
wherein the contact hole is disposed between the gate electrode and the compensation electrode, and in a direction perpendicular to the extension direction of the source electrode portion or the compensation portion, a minimum distance between the contact hole and the gate line is less than or equal to a width of the gate electrode;
wherein in a direction perpendicular to the extension direction of the source electrode portion or the compensation portion, a distance between the storage capacitor portion and the gate line is less than or equal to a distance between the source electrode portion and the gate line, and the distance between the storage capacitor portion and the gate line is less than or equal to a distance between the compensation portion and the gate line;
wherein the extension direction of the source electrode portion is parallel to the extension direction of the compensation portion, and the extension direction of the source electrode portion is opposite to the extension direction of the compensation portion.

12. The array substrate according to claim 11, wherein in a direction perpendicular to the extension direction of the source electrode portion or the compensation portion, a width of a part of the source electrode portion is equal to a width of the compensation portion.

13. The array substrate according to claim 11, wherein in the extension direction of the source electrode portion or the compensation portion, the source electrode portion at least partially overlaps the compensation portion or is at least partially staggered with the compensation portion.

14. The array substrate according to claim 11, wherein in the extension direction of the source electrode portion or the compensation portion, an edge of one of the storage capacitor portion and the array substrate side common electrode extends beyond an edge of the other on the same side; and
in a direction perpendicular to the extension direction of the source electrode portion or the compensation portion, an edge of one of the storage capacitor portion and the array substrate side common electrode extends beyond an edge of the other on the same side.

15. The array substrate according to claim 11, wherein in the extension direction of the source electrode portion or the compensation portion, a distance between the edge of the storage capacitor portion and an edge of the array substrate side common electrode on the same side ranges from 3 to 5 microns, and a distance between the gate electrode and the storage capacitor portion is greater than or equal to 4.3 microns.

16. The array substrate according to claim 14, wherein in the direction perpendicular to the extension direction of the source electrode portion or the compensation portion, and a distance between the edge of the storage capacitor portion and an edge of the array substrate side common electrode on the same side ranges from 3 to 5 microns, a width of the source electrode portion ranges from 7 to 10 microns.

17. The array substrate according to claim 11, wherein the array substrate further comprises a drain electrode, in the extension direction of the source electrode portion or the compensation portion, and a distance between the drain electrode and an edge of a side of the gate electrode near the storage capacitor portion is greater than or equal to 7 microns.
